(19) United States
(12) Patent Application Publication
(10) Pub. No.: US 2011/0304981 A1
(43) Pub. Date: Dec. 15, 2011

(54) COMPUTER SERVER SYSTEM AND COMPUTER SERVER THEREOF

(75) Inventor: WEN-HUNG HUANG, Tu-Cheng (TW)

(73) Assignee: HON HAI PRECISION INDUSTRY CO., LTD., Tu-Cheng (TW)

(21) Appl. No.: 12/885,570

(22) Filed: Sep. 19, 2010

(30) Foreign Application Priority Data
Jun. 15, 2010 (TW) 99119595

(51) Int. Cl. G06F 1/20; H05K 5/00

(52) U.S. Cl. 361/679.48; 361/679.54; 361/679.52; 361/679.46

(57) ABSTRACT

An exemplary computer server system includes a cabinet and a server mounted in the cabinet. The servers includes a casing, an electronic component mounted in the casing, a heat dissipation device for dissipating heat generated by the electronic component, and a fan module. The heat dissipation device includes a heat absorption portion and a heat dissipation portion. The heat absorption portion is arranged in the enclosure to absorb the heat generated by the electronic component. The heat dissipation portion is arranged between the enclosure and the fan module to dissipate the heat transferred to an outside of the enclosure.

### BACKGROUND

1. Technical Field

The present disclosure relates to computer servers, and more particularly to a computer server having a heat dissipation device for dissipating heat of the computer server.

2. Description of Related Art

Computer servers are known in the art and commonly used to process and store data and information in networks. Typically, a computer server includes an enclosure and a plurality of electronic components received in the enclosure. The electronic components may for example include one or more processors, random access memory (RAM), etc. During operation of the server, the electronic components generate considerable heat, which is required to be dissipated immediately. Conventionally, metallic heat sinks are mounted on the electronic components to absorb heat therefrom, and fans or fan modules are provided inside or outside the enclosure to cooperate with the heat sink. In particular, the fans or fan modules are used to generate airflow, which passes through the heat sinks to take the heat away.

To achieve a large heat dissipation area, a heat sink is often large and bulky. When airflow flows inside an enclosure, upstream sections of the airflow may be blocked by bulky heat sinks or various electronic components. This is liable to prevent the airflow from flowing toward other heat sinks located at downstream sections of the airflow. At the very least, the speed of the airflow at the downstream sections is liable to be reduced. Thus, the heat dissipation efficiency of the heat sinks at the downstream sections of the airflow is also reduced.

Accordingly, what is desired is a computer server which can overcome the above-described limitations.

### BRIEF DESCRIPTION OF THE DRAWINGS

FIG. 1 is an isometric, assembled view of a computer server system in accordance with an exemplary embodiment of the present disclosure.

FIG. 2 is an exploded view of a computer server of the computer server system of FIG. 1.

FIG. 3 is a schematic top plan view of a heat dissipation device of the computer server of FIG. 2.

### DETAILED DESCRIPTION

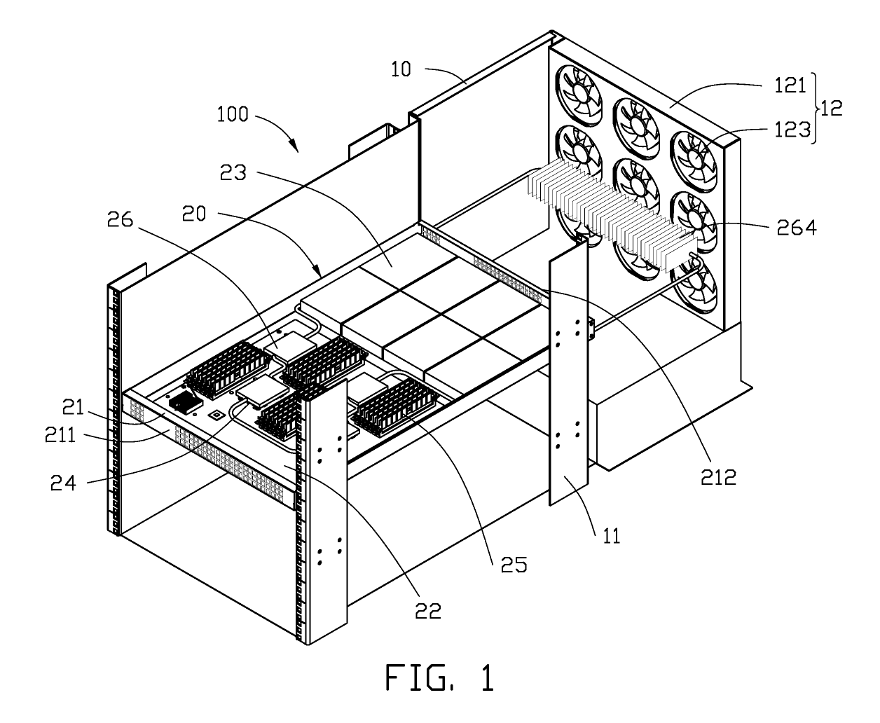

Referring to FIG. 1, a computer server system 100 according an exemplary embodiment of the present disclosure is shown. The server system 100 includes a cabinet 10, and a plurality of computer servers 20 stacked in the cabinet 10. For clarity, in the embodiment, only one server 20 is shown, and other servers 20 are omitted.

The cabinet 10 is a hollow metallic cuboid housing. A plurality of elongated supporting plates 11 are provided vertically in the cabinet 10 for supporting the servers 20. A fan module 12 is mounted at a rear side of the cabinet 10. The fan module 12 includes a receptacle 121 and a plurality of fans 123 mounted in the receptacle 121.

Each of servers 20 includes an enclosure 21, a circuit board 22 accommodated in the enclosure 21, a plurality of hard disks 23, a plurality of first electronic components 24 and second electronic components 25 mounted on the circuit board 22, and a heat dissipation device 26 mounted on the first electronic components 24.

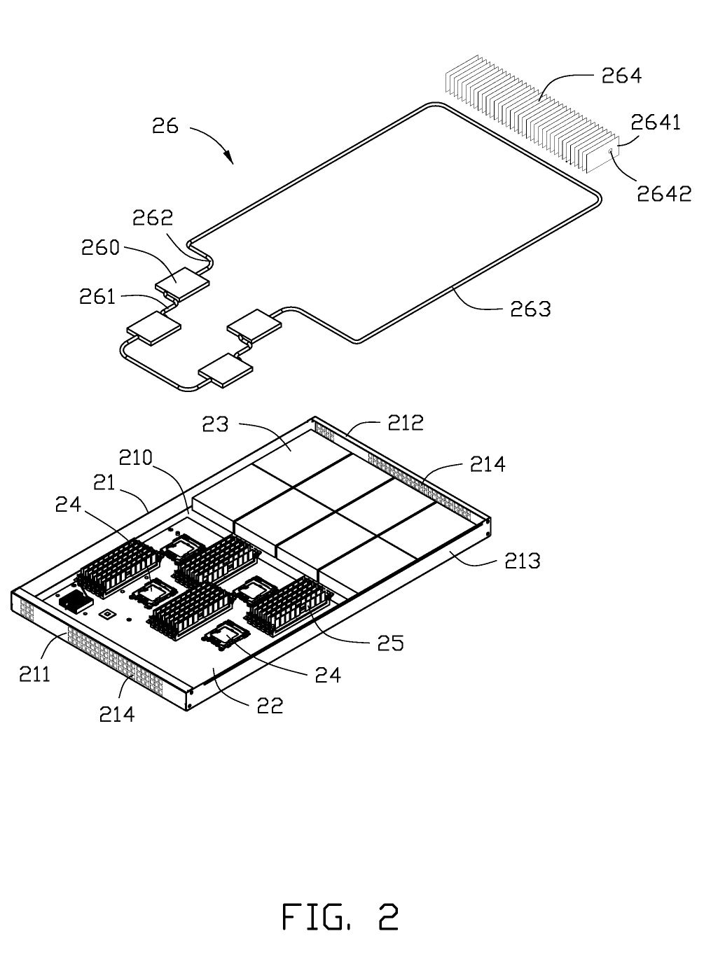

Referring also to FIG. 2, the enclosure 21 includes a rectangular base plate 210, a first side plate 211, and a second side plate 212 respectively formed at two opposite sides (i.e., front and rear sides) of the base plate 210, and a pair of third side plates 213 respectively formed at another two opposite sides (i.e., left and right sides) of the base plate 210. The first side plate 211 and the second side plate 212 each define a plurality of ventilation holes 214 therein. The fan module 12 is located outside the enclosure 21 and spaced from the second side plate 212, and is oriented to face the ventilation holes 214. The circuit board 22 is located adjacent to the first side plate 211 in the enclosure 21, and the hard disks 23 are located adjacent to the second side plate 212 in the enclosure 21, i.e. adjacent to the fan module 12. The first electronic components 24 and the second electronic components 25 are alternately mounted on the circuit board 22. Each first electronic component 24 has a size less than that of each second electronic component 25.

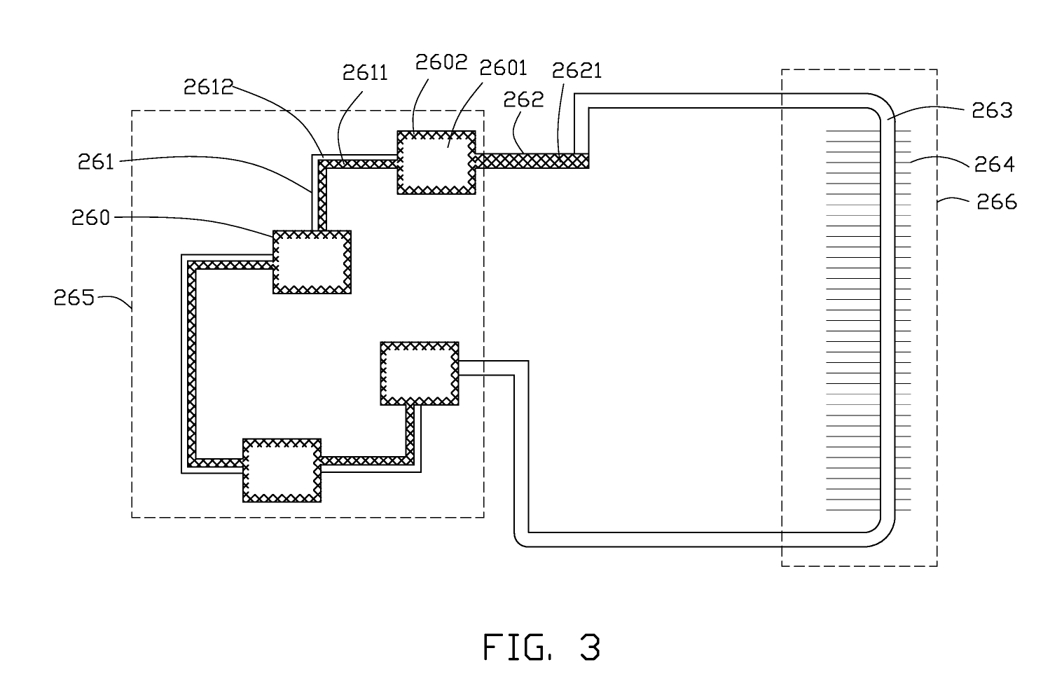

Referring also to FIG. 3, the heat dissipation device 26 includes a plurality of flat evaporators 260, a plurality of first pipelines 261, a second pipeline 262, a third pipeline 263, and a heat sink 264.

Each of the first pipelines 261 is provided with a first wick structure 2611 lining an inner wall thereof. A vapor passage 2612 is defined in each first pipeline 261 along an axial direction thereof.

Each of the evaporators 260 is a hollow casing made of heat conductive material, such as copper, aluminum, etc. A receiving space 2601 is defined in the evaporator 260. A second wick structure 2602 is provided in the receiving space 2601, lining an inner wall of the evaporator 260. The evaporators 260 are respectively attached on the first electronic components 24, for absorbing heat therefrom. The evaporators 260 are connected together by the first pipelines 261 in series to form a heat absorption section 265. The first wick structure 2611 of each first pipeline 261 connects with the second wick structures 2602 of two adjacent evaporators 260 which are respectively connected at two opposite ends of the first pipeline 261. The vapor passage 2612 of the first pipeline 261 communicates with the receiving spaces 2601 of the two adjacent evaporators 260 which are respectively connected at the two opposite ends of the first pipeline 261. A top of the evaporator 260 is located at a level below a top of the heat sink 264 to facilitate the airflow from the first side plate 211 of the computer server 20 to the heat sink 264, and the level of the top of the evaporator 260 is located below a top of the second electronic component 25 to facilitate airflow flowing through the second electronic component 25.

An end of the second pipeline 262 is connected with an evaporator 260 located at an end of the heat absorption section 265. The second pipeline 262 is provided with a third wick structure 2621. In particular, an inside of the second pipeline 262 is filled with the third wick structure 2621. The third wick structure 2621 is connected with the second wick structure 2602 of the evaporator 260.

The third pipeline 263 is hollow. An end of the third pipeline 263 is connected with the evaporator 260 located at the other end of the heat absorption section 265. The other end of the third pipeline 263 is connected with the other end of the second pipeline 262 to form a loop.

The heat sink 264 is located outside the enclosure 21 of the server 20, between the second side plate 212 of the enclosure 21 and the fan module 12. The heat sink 264 includes a plurality of fins 2641 stacked together in a horizontal direction. Each of the fins 2641 defines a through hole 2642 therein. The third pipeline 263 extends through the through holes 2642 of the fins 2641 to form a heat dissipation section 266. The heat dissipation section 266 is located outside of the enclosure 21, between the second side plate 212 of the enclosure 21 of the server 20 and the fan module 12.

The loop of the heat dissipation device 26 is evacuated during a process of production, and is filled with an appropriate quantity of working fluid with high enthalpy, such as water, alcohol, etc.

During operation of the server system 100, the fan module 12 is electrified to generate airflow which flows through the enclosure 21 of the server 20 and the heat sink 264 of the heat dissipation device 26. In one embodiment, the airflow flows in a direction from the first side plate 211 to the fan module 12 and then out of the cabinet 10 through the rear side of the cabinet 10. When the airflow flows through the enclosure 21, heat generated by the second electronic components 25 and hard disks 23 is taken away by the airflow. Heat generated by each first electronic component 24 is transferred to the corresponding evaporator 260. The working fluid contained in the evaporator 260 absorbs the heat and vaporizes into vapor. The vapor moves, bearing the heat, towards the third pipeline 263 through the vapor passage 2612 of the first pipeline 261. The vapor is condensed into condensate at the third pipeline 263, with the heat of the vapor being released to the third pipeline 263 and the heat sink 264 placed around the third pipeline 263. When the airflow flows through the heat sink 264, the heat of the heat sink 264 is taken away. Then the condensate in the third pipeline 263 is drawn back in turn by the third wick structure 2621 of the second pipeline 262, the second wick structures 2602 of the evaporators 260, and the first wick structures 2611 of the first pipelines 261 to the heat absorption section 265 where it is again available for evaporation.

In the present embodiment, the heat dissipation device 26 includes a heat absorption section 265 arranged in the enclosure 21 of the server 20 to absorb heat of the first electronic components 265, and a heat dissipation section 266 arranged outside the enclosure 21 of the server 20 to dissipate heat. The evaporators 260 of the heat absorption section 265 are respectively mounted on the first electronic components 25. Each evaporator 260 has a relatively small volume, thus avoiding blockage of the airflow which flows in the enclosure 21 of the server 20. The heat sink 264 of the heat dissipation section 266 is arranged outside the enclosure 21 of the server 20, and is thermally connected with the evaporators 260 through the second pipeline 262 and the third pipeline 263. Therefore, the heat sink 264 can be configured with a larger size to provide a large heat dissipation area. In addition, the heat dissipation device 26 transfers heat through phase change of the working fluid contained therein, whereby heat generated by the first electronic components 25 can be promptly transferred from the evaporators 260 to the heat sink 264.

It is to be understood, however, that even though numerous characteristics and advantages of the present embodiment(s) have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A computer server, comprising:
an enclosure;
an electronic component accommodated in the enclosure; and
a heat dissipation device comprising a heat absorption section and a heat dissipation section, the heat absorption section being arranged in the enclosure and thermally attached to the electronic component to absorb heat of the electronic component, and the heat dissipation section being arranged outside the enclosure to dissipate the heat conveyed from the heat absorption section to an outside of the enclosure.

2. The computer server of claim 1, wherein the heat absorption section comprises an evaporator, the heat dissipation section comprises a heat sink, at least one pipeline is connected between the evaporator and the heat sink to form a loop, the loop is filled with working fluid for transferring heat through phase change.

3. The computer server of claim 2, wherein the heat absorption section comprises a plurality of evaporators and a plurality of first pipelines, each evaporator defines a receiving space therein, each first pipeline defines a vapor passage therein, the evaporators are connected together by the first pipelines in series to form the heat absorption section, the vapor passage of each first pipeline communicates with the receiving spaces of two adjacent evaporators which are respectively connected at two opposite ends of the first pipeline.

4. The computer server of claim 3, wherein the first pipelines each are provided with a first wick structure lining an inner wall thereof, each evaporator is provided with a second wick structure lining an inner wall thereof, and the first wick structure of each first pipeline connects with the second wick structures of the two adjacent evaporators which are respectively connected at the two opposite ends of the first pipeline.

5. The computer server of claim 3, wherein the heat dissipation section further comprises a third pipeline, the third pipeline is hollow and extends through the heat sink, and two opposite ends of the third pipeline are respectively connected with two evaporators located at two opposite ends of the heat absorption section.

6. The computer server of claim 5, wherein the heat dissipation device further comprises a second pipeline, the second pipeline is filled with a third wick structure, an end of the third pipeline is connected with the evaporator located at an end of the heat absorption section through the second pipeline, the third wick structure is connected with the second wick structure of the evaporator.

7. The computer server of claim 3, wherein the enclosure comprises a base plate, and a first side plate and a second side plate formed at two opposite sides of the base plate, the first side plate and the second side plate each define a plurality of ventilating holes, the heat absorption section is located adjacent to the first side plate in the enclosure, and the heat dissipation section is located outside the enclosure and spaced from the second side plate.

8. A computer server system, comprising:
a cabinet;
a fan module mounted in the cabinet; and
a plurality of computer servers stacked in the cabinet, each of the computer servers comprising an enclosure, an electronic component accommodated in the enclosure, and a heat dissipation device for dissipating heat of the electronic component;
the heat dissipation device comprising a heat absorption section and a heat dissipation section, the heat absorption section being arranged in the enclosure and thermally attached to the electronic component to absorb heat of the electronic component, and the heat dissipation section being arranged between the enclosure and the fan module to dissipate the heat conveyed from the heat absorption section to an outside of the enclosure.

9. The computer server system of claim 8, wherein the heat absorption section comprises an evaporator, the heat dissipation section comprises a heat sink, at least one pipeline is connected between the evaporator and the heat sink to form a loop, the loop is filled with working fluid for transferring heat through phase change.

10. The computer server system of claim 9, wherein the heat absorption section comprises a plurality of evaporators and a plurality of first pipelines, each evaporator defines a receiving space therein, each first pipeline defines a vapor passage therein, the evaporators are connected together by the first pipelines in series to form the heat absorption section, the vapor passage of each first pipeline communicates with the receiving spaces of two adjacent evaporators which are respectively connected at two opposite ends of the first pipeline.

11. The computer server system of claim 10, wherein the first pipelines each are provided with a first wick structure lining an inner wall thereof, each evaporator is provided with a second wick structure lining an inner wall thereof, and the first wick structure of each first pipeline connects with the second wick structures of the two adjacent evaporators which are respectively connected at the two opposite ends of the first pipeline.

12. The computer server system of claim 10, wherein the heat dissipation section further comprises a third pipeline, the third pipeline is hollow and extends through the heat sink, and two opposite ends of the third pipeline are respectively connected with two evaporators located at two opposite ends of the heat absorption section.

13. The computer server system of claim 12, wherein the heat dissipation device further comprises a second pipeline, the second pipeline is filled with a third wick structure, an end of the third pipeline is connected with the evaporator located at an end of the heat absorption section through the second pipeline, the third wick structure is connected with the second wick structure of the evaporator.

14. The computer server system of claim 10, wherein the enclosure comprises a base plate, and a first side plate and a second side plate formed at two opposite sides of the base plate, the first side plate and the second side plate each define a plurality of ventilating holes, the heat absorption section is located adjacent to the first side plate in the enclosure, and the heat dissipation section is located outside the enclosure and spaced from the second side plate.

15. The computer server system of claim 8, wherein the fan module comprises a receptacle and a plurality of fans mounted in the receptacle, and the fan module are orientated to face the heat dissipation section of the heat dissipation device.

16. A computer server system, comprising:
a cabinet;
a fan module mounted in the cabinet, the fan module comprising a plurality of fans; and
a plurality of computer servers stacked in the cabinet, each of the computer servers comprising an enclosure, an electronic component accommodated in the enclosure, and a heat dissipation device for dissipating heat of the electronic component;
the heat dissipation device comprising a heat absorption section and a heat dissipation section, the heat absorption section being arranged in the enclosure, and comprising a flat evaporator thermally attached on the electronic component to absorb heat of the electronic component;
the heat dissipation section being arranged between the enclosure and the fan module to dissipate the heat conveyed from the heat absorption section, the heat dissipation section comprising a heat sink;
the fan module configured to provide airflow in a direction from an end of the computer server farthest from the heat sink to the heat sink, such that the air flows through the heat sink to an outside of the cabinet farthest from the computer server; and
a top of the flat evaporator being located at a level below a top of the heat sink to facilitate the airflow from an inside of the computer server to the heat sink.

17. The computer server system of claim 16, wherein each of the computer servers further comprises a second electronic component accommodated in the enclosure, and the level of the top of the flat evaporator is located below a top of the second electronic component to facilitate airflow through the second electronic component.
